(19) United States
(12) Patent Application Publication
(10) Pub. No.: US 2026/0353904 A1
(43) Pub. Date: Nov. 5, 2026

(54) 2D MOS2 ORGANIC PHOTODIODE WITH AN ULTRA-HIGH LINEAR DYNAMIC RANGE MANUFACTURING METHOD AND ORGANIC PHOTODIODE MANUFACTURED THEREBY

(71) Applicant: KOREA UNIVERSITY RESEARCH AND BUSINESS FOUNDATION, Seoul (KR)

(72) Inventors: Jae Won SHIM, Seoul (KR); Gyeong Min LEE, Seongnam-si (KR)

(21) Appl. No.: 19/552,316

(22) Filed: Feb. 27, 2026

(30) Foreign Application Priority Data
Apr. 24, 2025 (KR) 10-2025-0053798

(51) Int. Cl. H10K 30/35; H10K 30/85; H10K 30/86; H10K 71/12; H10K 85/10; H10K 85/20

(52) U.S. Cl. CPC H10K 30/35; H10K 71/12; H10K 85/113; H10K 85/211; H10K 30/85; H10K 30/86

(57) ABSTRACT

The present disclosure discloses a 2D MoS₂ organic photodiode with an ultra-high linear dynamic range and a method for manufacturing the same. According to the present disclosure, a method for manufacturing an organic photodiode includes: forming a transparent electrode on a substrate; forming an electron transport layer on the transparent electrode; forming, on the electron transport layer, an organic bulk heterojunction photoactive layer having MoS₂ added at a predetermined volume percent relative to a total solution; forming a charge transport layer on the organic photoactive layer; and forming an upper electrode on the charge transport layer.

### CROSS-REFERENCE TO RELATED APPLICATION

This application claims under 35 U.S.C. § 119(a) the benefit of Korean Patent Application No. 10-2025-0053798 filed on Apr. 24, 2025, the entire contents of which are incorporated herein by reference.

### BACKGROUND

### (a) Technical Field

The present disclosure relates to a two-dimensional (2D) MoS₂ organic photodiode with an ultra-high linear dynamic range and a method for manufacturing the same.

### (b) Background Art

The recent advancements in various advanced electronic devices, such as optical communication systems, image sensors, and biosensors, have led to a continuous increase in demand for high-performance photodiodes.

In particular, organic photodiodes (OPDs) are attracting attention as a next-generation photodetection technology due to their excellent light absorption characteristics across a wide range of wavelengths and their flexible structure.

Furthermore, unlike the conventional inorganic semiconductor-based photodetectors, the organic photodiodes may be fabricated using low-temperature solution processes, reducing manufacturing costs and increasing their potential for application in flexible electronic devices.

However, the organic photodiodes face technical limitations due to the inherent low carrier mobility and high nonradiative recombination characteristics of organic semiconductors, resulting in limited photoresponsivity and a low linear dynamic range (LDR).

Furthermore, to achieve high light detection accuracy and a high signal-to-noise ratio (SNR), both minimal dark current and high photocurrent should be achieved simultaneously. However, the existing technologies struggle to improve performance due to the conflicting characteristics of these two factors.

### SUMMARY OF THE DISCLOSURE

To address the above-mentioned problems of the prior art, the present disclosure proposes a two-dimensional (2D) MoS₂ organic photodiode with an ultra-high linear dynamic range and low noise characteristics, and a method for manufacturing the same.

To achieve the above-mentioned object, according to an aspect of the present disclosure, a method for manufacturing an organic photodiode includes: forming a transparent electrode on a substrate; forming an electron transport layer on the transparent electrode; forming, on the electron transport layer, an organic bulk heterojunction photoactive layer having MoS₂ added at a predetermined volume percent relative to a total solution; forming a charge transport layer on the organic photoactive layer; and forming an upper electrode on the charge transport layer.

The forming of the organic photoactive layer may include depositing a donor-acceptor mixed layer having the MoS₂ added at the predetermined volume percent relative to the total solution onto a base matrix containing a 1:1 mixture of poly(3-hexylthiophene) (P3HT) as a donor and a fullerene derivative (ICBA) as an acceptor, by spin coating.

The MoS₂ may be mixed at 1 to 20 volume percent.

The MoS₂ may be mixed at 1 to 10 volume percent.

The organic photodiode may suppress Langevin recombination, which occurs at increased light intensity due to the addition of the MoS₂, to maintain linearity even in a high-light intensity region and keep a noise level even in a low-light intensity region at a femtoampere (fA) range.

The organic photodiode may have a linear dynamic range (LDR) of at least about 170 dB and a detectivity of at least 3×10¹² Jones due to the addition of the MoS₂.

According to another aspect of the present disclosure, an organic photodiode includes: a substrate; a transparent electrode formed on the substrate; an electron transport layer formed on the transparent electrode; an organic photoactive layer formed on the electron transport layer and composed of an organic bulk heterojunction having MoS₂ added at a predetermined volume percent relative to a total solution; a charge transport layer formed on the organic photoactive layer; and an upper electrode formed on the charge transport layer.

According to the present disclosure, by introducing MoS₂, a 2D transition metal dichalcogenide material, into the organic photoactive layer at an optimal concentration, to effectively suppress the nonradiative Langevin recombination, it is possible to implement both the ultra-high linear dynamic range and ultra-low femtoampere-level noise characteristics.

### BRIEF DESCRIPTION OF DRAWINGS

FIG. 1 is a diagram showing a structure of a two-dimensional (2D) molybdenum disulfide (MoS₂)-added organic photodiode with low noise characteristics and ultra-high linear dynamic range, according to a preferred embodiment of the present disclosure.

FIG. 2 is a schematic diagram showing an operational concept of an organic photodiode according to the present embodiment.

FIG. 3 is a diagram illustrating the effect of increased charge lifetime (red curve) confirmed through transient absorption measurements and the characteristic of measured noise current being maintained at the femtoampere level.

FIG. 4 is a schematic diagram showing the results of analyzing the kinetics of charge carriers within an organic photoactive layer according to the present embodiment.

FIG. 5 is a graph comparing a built-in voltage (Vbi) and changes in total carrier density and free carrier density obtained through Mott-Schottky analysis.

FIG. 6 is a graph comparing the Langevin recombination coefficient and the variation of open-circuit voltage (Voc) with light intensity according to the addition of MoS₂.

FIG. 7 is a graph comparing external quantum efficiency (EQE) spectra of organic photodiodes according to MoS₂ addition ratios (w/o, w/1 vol %, w/10 vol %).

FIG. 8 is a graph comparing the frequency response characteristics of OPD according to MoS₂ concentration.

FIG. 9 is a graph illustrating the time-transient current measured in the dark state of the OPD to demonstrate the low-noise characteristics of the photodiode according to the present embodiment, and comparing the results measured under the same conditions for each sample according to the addition ratio (w/o, w/1 vol %, w/10 vol %) of MoS₂.

FIG. 10 is a graph comparing the noise current spectra of the organic OPD in a frequency domain, and visualizes the noise characteristics up to the low-frequency band (~10 Hz or less) as the addition ratio (w/o, w/1 vol %, w/10 vol %) of 2D MoS₂ increases.

FIG. 11 illustrates the photocurrent (upper graph) and photoresponsivity (lower graph) simultaneously according to the change in optical power, and is a result that may confirm the linear dynamic range and Langevin recombination suppression effect of the organic photodiode according to the addition ratio (w/o, w/1 vol %, w/10 vol %) of two-dimensional MoS₂.

FIG. 12 illustrates the results of grazing incidence wide-angle X-ray scattering (GIWAXS) that analyzed the crystal structure and orientation in the organic photoactive layer thin film according to the addition ratio (w/o, w/1 vol %, w/10 vol %) of two-dimensional MoS₂.

### DETAILED DESCRIPTION

Since the present disclosure may be variously modified and have several exemplary embodiments, specific exemplary embodiments will be illustrated in the accompanying drawings and be described in detail in a detailed description. However, it is to be understood that the present disclosure is not limited to a specific exemplary embodiment, but includes all modifications, equivalents, and substitutions without departing from the scope and spirit of the present disclosure.

The terms used in the present specification are used only in order to describe specific embodiments rather than limiting the present disclosure. Singular expressions are intended to include plural expressions unless the context clearly represents otherwise. It should be further understood that the term “include” or “have” used in the present specification specifies the presence of features, numerals, steps, operations, components, parts mentioned in the present specification, or combinations thereof, but does not preclude the presence or addition of one or more other features, numerals, steps, operations, components, parts, or combinations thereof.

In addition, the components of the embodiments described with reference to each drawing are not limited only to the specific embodiments, and may be implemented to be included in other embodiments within the scope in which the technical idea of the present disclosure is maintained. In addition, it is also obvious that multiple embodiments may be re-implemented as one integrated embodiment even if a separate description is omitted.

In addition, in the description with reference to the accompanying drawings, the same components are given the same or related reference numerals regardless of the drawing numerals, and redundant descriptions thereof will be omitted. When it is determined that the detailed description of the known art related to the present disclosure may unnecessary obscure the gist of the present disclosure, a detailed description therefor will be omitted.

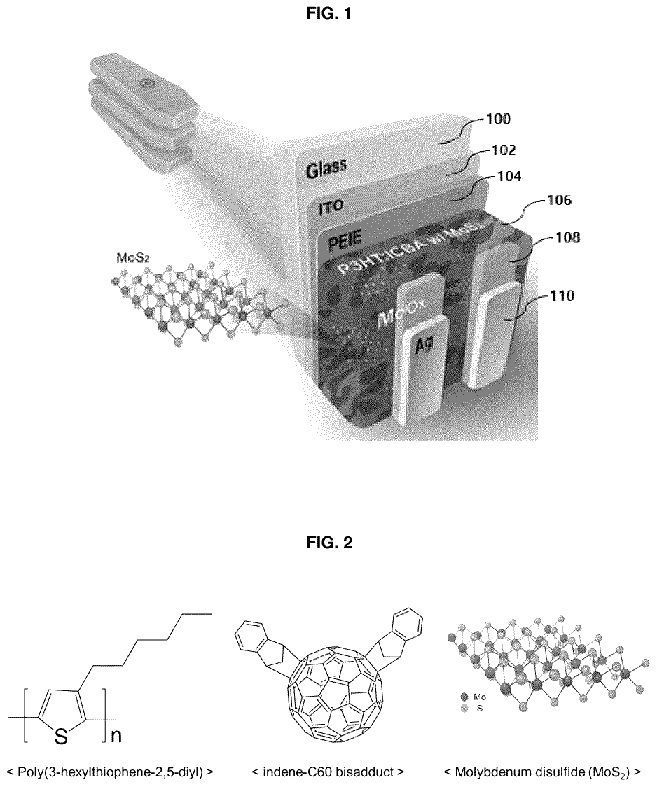

FIG. 1 is a diagram showing a structure of a two-dimensional (2D) molybdenum disulfide (MoS₂)-added organic photodiode with low noise characteristics and ultra-high linear dynamic range, according to a preferred embodiment of the present disclosure, and FIG. 2 is a schematic diagram illustrating an operational concept of an organic photodiode according to the present embodiment.

As illustrated in FIG. 1, the organic photodiode according to the present embodiment may include a substrate 100, a transparent electrode layer 102, an electron transport layer 104, an organic photoactive layer 106, a charge transport layer 108, and a metal electrode 110.

The substrate may be a glass substrate, and the transparent electrode layer 102, such as ITO, is formed on the substrate 100.

Furthermore, the electron transport layer 104 made of polyethyleneimide (PEIE) is deposited on the transparent electrode layer 102 by spin coating.

The organic photoactive layer 106 according to the present embodiment is formed on the electron transport layer 104 and may be composed of poly(3-hexylthiophene) (P3HT), indene-C60 bisadduct (ICBA), and two-dimensional molybdenum disulfide (MoS₂) constituting an organic bulk heterojunction (BHJ).

FIG. 2 is a diagram showing chemical formulas of the poly(3-hexylthiophene) (P3HT), the indene-C60 bisadduct (ICBA), and the two-dimensional molybdenum disulfide (MoS₂) according to the present embodiment.

The organic photoactive layer 106 according to the present embodiment is manufactured by adding two-dimensional molybdenum disulfide (MoS₂) at a certain ratio (e.g., w/1 vol % to w/20 vol %) to a base matrix in which poly(3-hexylthiophene) (P3HT) and a fullerene derivative ICBA are mixed at a 1:1 weight ratio.

According to the present embodiment, there is provided the organic photoactive layer that includes a donor-acceptor mixed layer in which (i) poly(3-hexylthiophene) (P3HT) as an electron donor and (ii) a fullerene derivative (ICBA) as an electron acceptor are mixed at a 1:1 weight ratio, and (iii) MoS₂ is added at a ratio of 1 vol % to 10 vol % relative to the total solution.

More specifically, according to the present embodiment, MoS₂ (sigma aldrich) was dispersed in chlorobenzene to prepare a stock dispersion with a concentration of 1.0 mg/mL. Next, this stock dispersion was ultrasonically dispersed for 60 minutes to ensure uniform dispersion. To achieve concentrations of 1 vol % and 10 vol %, 0.1 mL and 1.0 mL of the stock dispersion were added to 9.9 mL and 9.0 mL of pure chlorobenzene, respectively, so the final volume becomes 10 mL.

After high-purity P3HT and ICBA are added to the MoS₂-containing chlorobenzene solution thus prepared in a 1:1 weight ratio, and dissolved to achieve a total concentration of 100 mg/mL, the solution is stirred in a nitrogen-atmosphere glovebox at 75 °C for at least 3 hours to produce a photoactive solution for BHJ and is deposited by spin coating, thereby forming an organic photoactive layer. By incorporating MoS₂, (i) Langevin recombination, which occurs when light intensity increases, is suppressed, maintaining linearity even in a high-light intensity region (greater than 17 mW/cm²), and (ii) noise levels are significantly reduced to a femtoampere (fA) range even in a low-light intensity region, enabling a linear dynamic range (LDR) of up to approximately 170 dB or more and a detectivity of 3×10¹² Jones or more to be achieved.

The charge transport layer 108 composed of a metal oxide layer (MoOx) is deposited on the organic photoactive layer 106 using a thermal evaporator.

Finally, the metal electrode 110 composed of silver (Ag) is deposited on the charge transport layer 108 using the thermal evaporator, thereby completing the entire device.

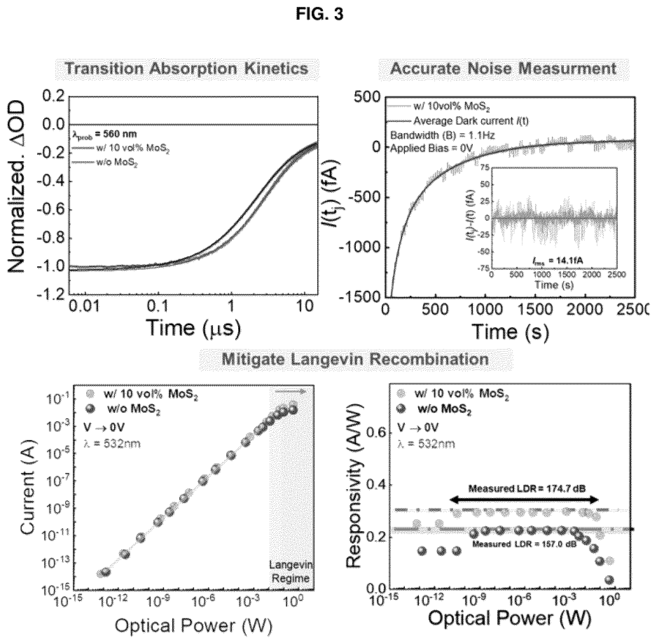

FIGS. 3(a) and 3(b) are diagrams illustrating the effect of increased charge lifetime (red curve) confirmed through transient absorption measurements and the characteristic of measured noise current being maintained at the femtoampere level.

In addition, FIGS. 3(c) and 3(d) show photocurrent and responsivity depending on light intensity.

Referring to FIG. 3, it may be confirmed that, when MoS₂ is added (red curve, w/10 vol %), compared to the case when MoS₂ is not added (gray curve), linearity is maintained without saturation even in a higher light intensity region.

FIG. 4 is a schematic diagram showing the results of analyzing the kinetics of charge carriers within an organic photoactive layer according to the present embodiment.

FIGS. 4(a) to 4(c) are diagrams comparing the transient absorption, i.e., the time-dependent change in optical absorption on the nanosecond scale, of P3HT:ICBA with MoS₂ added at w/o, w/1 vol %, and w/10 vol %, respectively, in which it can be observed that as the MoS₂ concentration increases, charge recombination is suppressed, thereby extending the carrier lifetime.

FIGS. 4(d) to 4(e) are time-resolved curves extracted at specific wavelengths (e.g., 560 nm and 615 nm), in which it may be seen that the decay of photoinduced carriers (charges generated by photoexcitation) occurs more slowly in samples containing 1 vol % and 10 vol % MoS₂.

Consequently, the transient absorption data presented in FIG. 4 may confirm that the two-dimensional MoS₂ additive reduces nonradiative recombination pathways within the organic photoactive layer and improves charge extraction efficiency.

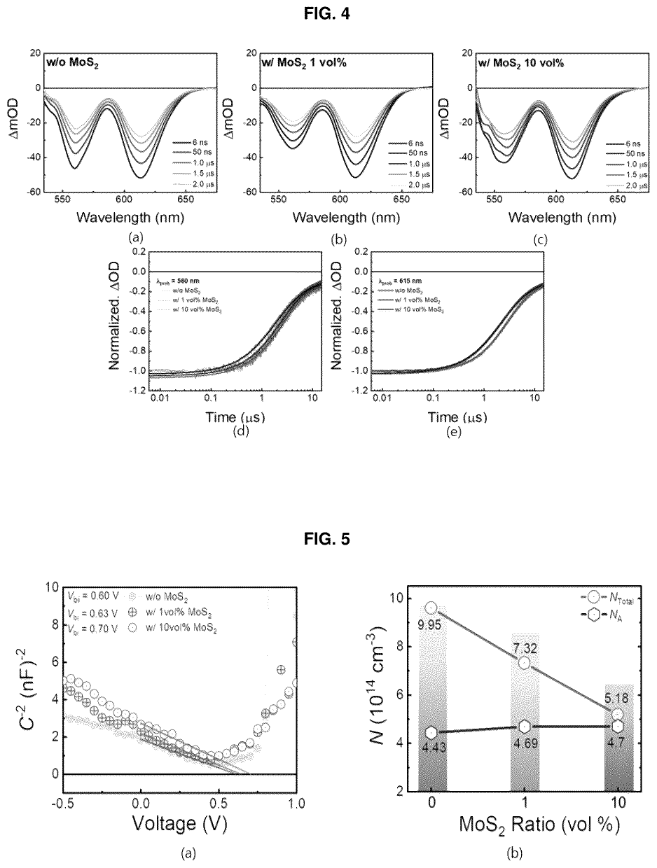

FIG. 5 is a graph comparing a built-in voltage (Vbi) and changes in total carrier density and free carrier density obtained through Mott-Schottky analysis.

FIG. 5(a) illustrates a Mott-Schottky plot measured at a frequency of 1 kHz, which shows that the built-in voltage gradually increases when MoS₂ is added at concentrations of w/1 vol % and w/10 vol % relative to w/o. Accordingly, it may be seen that the electric field within the organic photoactive layer is strengthened, resulting in improved charge separation and transport.

FIG. 5(b) illustrates a total carrier density (Nₜₒₜₐₗ) and free carrier density (N_{A}) calculated in the low-frequency (1 kHz) and high-frequency (1 MHz) ranges, respectively, and illustrates that, as the MoS₂ addition ratio increases, the charge trap density decreases, and the number of free carriers slightly increases or remains constant. This suggests that the addition ratio contributes to suppressing charge recombination and enhancing photoresponse. Meanwhile, as will be described below, it can be seen that when the MoS₂ addition ratio is 10 volume percent or more, the total number of carriers decreases again. Accordingly, it can be seen that the optimal concentration of MoS₂ in the organic photoactive layer is 10 volume percent.

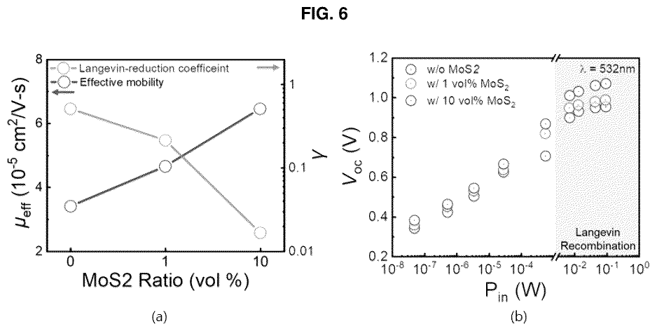

FIG. 6 is a graph comparing the Langevin recombination coefficient and the variation of open-circuit voltage (Voc) with light intensity according to the addition of MoS₂.

FIG. 6(a) illustrates that, as the MoS₂ addition ratio (w/o, w/1 vol %, w/10 vol %) in the P3HT:ICBA-based organic photoactive layer increases, the Langevin recombination coefficient significantly decreases, and at the same time the effective carrier mobility (μ_{eff}) improves. This suggests that suppression of charge recombination within the organic BHJ contributes to maintaining the photocurrent without saturation even in higher light intensity regions.

FIG. 6(b) shows an open-circuit voltage (V_{oc}) measured at various light intensities (Pin). As the MoS₂ addition ratio increases, γ (the Langevin recombination coefficient) decreases, leading to a higher V_{oc} at the same light intensity.

In particular, it shows that the photoresponse is maintained even in the high-light intensity region of 10 mW or higher due to the γ reduction effect, confirming that this is a key factor in achieving a wide dynamic range.

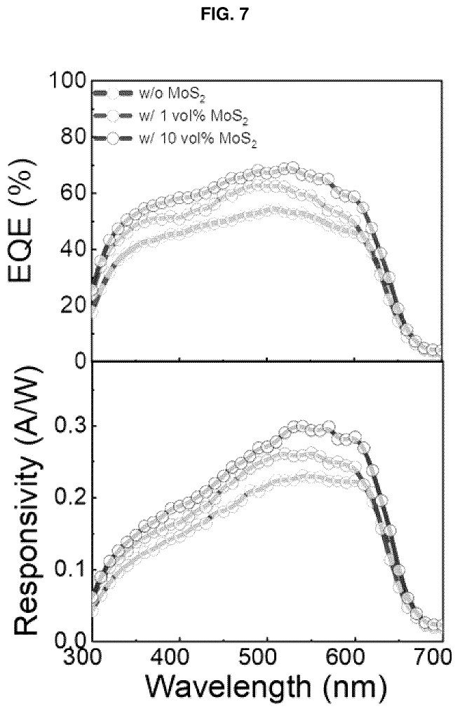

FIG. 7 is a graph comparing external quantum efficiency (EQE) spectra of organic photodiodes according to MoS₂ addition ratios (w/o, w/1 vol %, w/10 vol %).

As illustrated in FIG. 7, as the MoS₂ addition ratio increases, the EQE shows a general improvement across the entire optical wavelength range (approximately 300 to 700 nm). In particular, the 10 vol % concentration sample achieved an EQE approximately 10 to 20% higher than that of w/o MoS₂, demonstrating significant improvements in light absorption and charge extraction efficiency.

This increase in the EQE may be interpreted as the result of the MoS₂ additive suppressing the charge recombination within the BHJ and forming the effective charge transport pathway, thereby enhancing the light-to-current conversion efficiency. This effect serves as a key technological basis for low noise and a wide dynamic range, and offers significant advantages in high-sensitivity image sensors and photodetector applications.

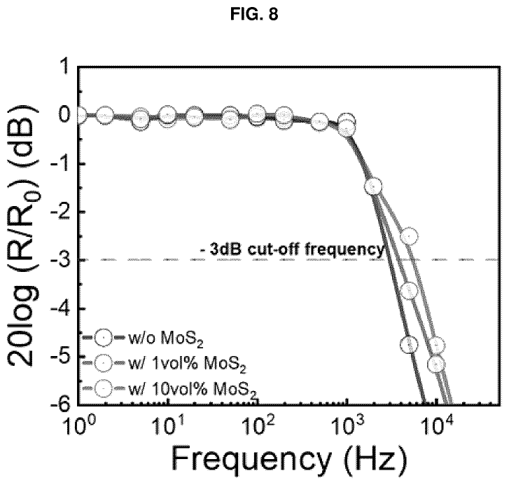

FIG. 8 is a graph comparing the frequency response characteristics of OPD according to MoS₂ concentration.

The horizontal axis represents frequency (Hz), and the vertical axis represents the normalized magnitude (e.g., normalized response) of the output voltage (or current) of the organic photodiode. The graph shows a response that remains constant up to several kHz bands, but then drops sharply at a specific point (−3 dB point).

As illustrated in FIG. 8, the sample without MoS₂ (w/o MoS₂) exhibits approximately 3 kHz, the sample with 1 vol % MoS₂ exhibits approximately 6 kHz, and the sample with 10 vol % MoS₂ exhibits a −3 dB cutoff frequency near 8 kHz. This suggests that the addition of MoS₂ additive enhances charge mobility and improves internal carrier dynamics, thereby maintaining a stable signal response up to higher frequency bands.

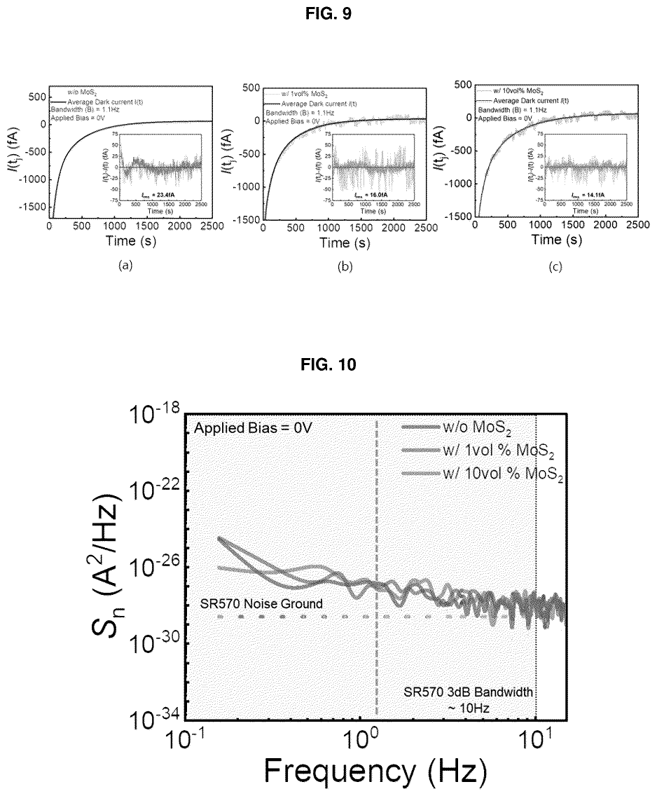

FIG. 9 is a graph illustrating the time-transient current measured in the dark state of the OPD to demonstrate the low-noise characteristics of the photodiode according to the present embodiment, and comparing the results measured under the same conditions for each sample according to the addition ratio (w/o, w/1 vol %, w/10 vol %) of MoS₂.

For the measurement, a triaxial cable was connected to a source meter such as the Keithley 2636B, and the organic photodiode device was monitored at room temperature (approximately 300 K) under dark conditions for an extended period (e.g., 30 minutes) to track the dark current, I(tⱼ). After collecting N discrete data points for each sample (e.g., N=3000), the stabilized average dark current, I(t), and the noise components were separated and analyzed.

An average dark current is calculated by the following Equation.

$$I ( t ) = \frac{1}{N} {\sum }_{j = 1}^{N} I ( {t}_{j} ) \qquad [ Equation 1 ]$$

The noise current Iᵣₘₛ is calculated according to the following Equation 2. That is, the noise current is defined as the root mean square (RMS) of the residuals obtained by subtracting the mean from the discretized data set.

$${I}_{rms} = \sqrt{{( I ( {t}_{j} ) - I ( t ) )}^{2}} = \sqrt{{N}^{- 1} \times {\sum }_{j = 1}^{j = N} {[ I ( {t}_{j} ) - I ( t ) ]}^{2}} \qquad [ Equation 2 ]$$

As illustrated in FIG. 9, the samples with 1 vol % and 10 vol % MoS₂ added (w/o) exhibited smaller current fluctuations (noise) compared to the unadded (w/o) sample, achieving low noise levels on the femtoampere (fA) scale. This suggests that the addition of MoS₂ reduced charge traps within the BHJ, suppressing microcurrent fluctuations in the dark state.

As a result, the organic photodiode with MoS₂ additive according to the present embodiment (i) maintains a stable dark current throughout the entire measurement time range, and (ii) exhibits a trace amount of noise current, making it suitable for implementing high sensitivity and a wide dynamic range, as may be seen specifically in FIG. 9. The time-transient current-based RMS noise analysis may intuitively evaluate the inherent low-noise characteristics of the device, excluding external causes (thermal noise, short-circuit noise, etc.).

FIG. 10 is a graph comparing the noise current spectra of the organic OPD in a frequency domain, and visualizes the noise characteristics up to the low-frequency band (~10 Hz or less) as the addition ratio (w/o, w/1 vol %, w/10 vol %) of 2D MoS₂ increases.

The horizontal axis of the graph represents frequency (Hz), and the vertical axis represents noise spectral density (Sn, unit: A²/Hz). This is compared with the internal noise level (SR570 Noise Ground) provided by the preamplifier SR570 (Stanford Research Systems) low-noise amplifier.

The three organic photodiodes maintain low noise levels in the ~10 to 29 Hz range. This shows values similar to the RMS noise levels of the time-transient current in FIG. 9, confirming the reliability of the RMS noise values of the three organic photodiodes.

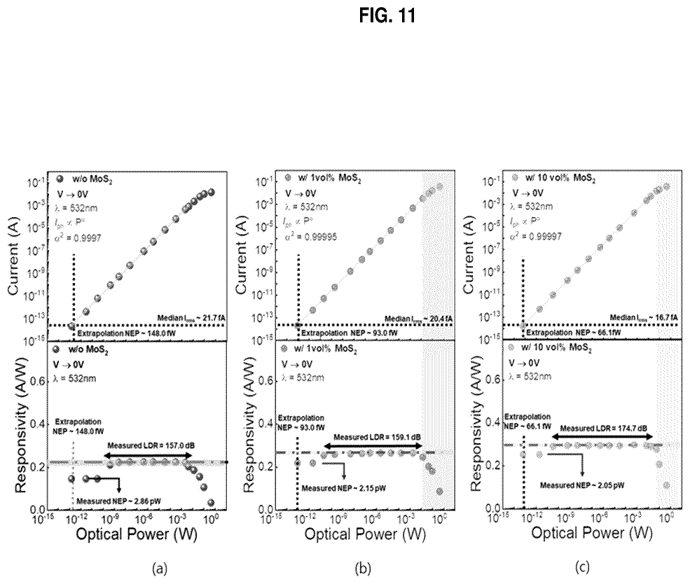

FIG. 11 shows the photocurrent (upper graph) and photoresponsivity (lower graph) simultaneously according to the change in optical power, and is a result that may confirm the linear dynamic range and Langevin recombination suppression effect of the organic photodiode according to the addition ratio (w/o, w/1 vol %, w/10 vol %) of two-dimensional MoS₂.

The top graph of FIG. 11 illustrates that even when the light intensity increases, the MoS₂-added samples (w/1 vol %, w/10 vol %) maintain a constant linearity (Linear Fit, R²>0.999) in their photocurrents, confirming a dynamic range approximately 10 to 20 dB wider than that of the sample without MoS₂ addition. This is interpreted as a result of Langevin recombination being suppressed even at high-light intensity region, significantly reducing charge recombination.

The bottom graph of FIG. 11 shows the photoresponsivity (A/W) measured under the same conditions. It illustrates that as the MoS₂ concentration (e.g., w/10 vol %) increases, the photoresponsivity is relatively well maintained in the low-light intensity region, and the decrease remains small even in the high-light intensity region, demonstrating a linear dynamic range of 170 dB or more (e.g., 174.7 dB for w/10 vol %).

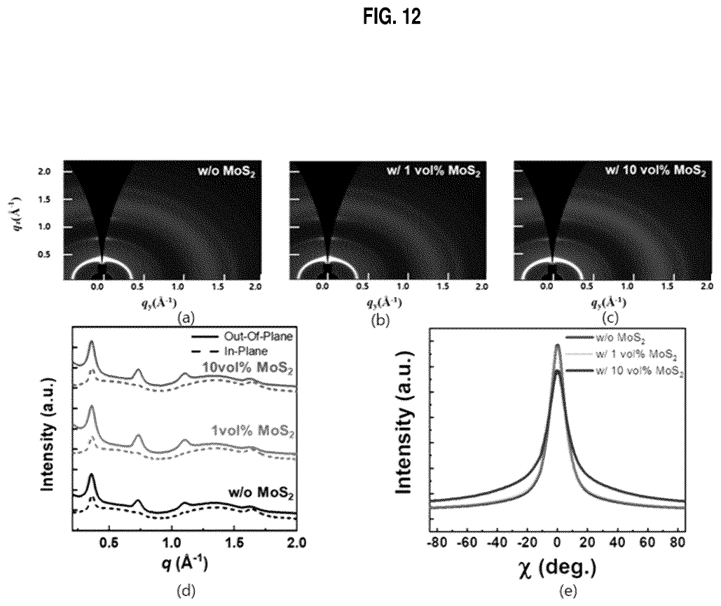

FIG. 12 illustrates the results of grazing incidence wide-angle X-ray scattering (GIWAXS) that analyzed the crystal structure and orientation in the organic photoactive layer thin film according to the addition ratio (w/o, w/1 vol %, w/10 vol %) of two-dimensional MoS₂.

FIGS. 12(a) to 12(c) show the two-dimensional reciprocal space maps (RSMs) obtained for each sample, where the (100) lamellar stacking distance and the (010) π-π stacking distance are identified from the Bragg diffraction patterns.

FIGS. 12(a) to 12(c) illustrate that the fine crystal orientation (face-on/edge-on ratio) within the thin film varies depending on the amount of MoS₂ added. This may contribute to enhancing charge mobility and suppressing nonradiative recombination.

Furthermore, FIG. 12(d) illustrates the diffraction intensity separated into the in-plane and out-of-plane directions, and FIG. 12(e) shows a diffraction intensity according to an azimuthal angle (φ or χ). It may be seen that the face-on stacking component slightly increases in the sample with 10 vol % MoS₂ addition.

This suggests that as the MoS₂ addition ratio increases, the face-on component partially increases to facilitate carrier transport in the vertical direction (normal to the substrate), providing a structural basis for maintaining high responsivity and a wide linear dynamic range even in the high-light intensity region of the OPD in the present embodiment.

Table 1 below illustrates the photodetection performance of the OPD according to the MoS₂ addition concentration.

TABLE 1

| | | | Median RMS | | |
|---|---|---|---|---|---|
| | | | Noise Current | D* | LDR |
| Materials | λ(nm) | [symbol] (A/W) | (A) | (Jones) | (dB) |
| w/o MoS₂ | 532 | 0.21 | 2.15 × 10⁻¹⁵ | 1.43 × 10⁻¹ [symbol] | 157.0 |
| w/1 vol % | 532 | 0.25 | 20.4 × 10⁻¹⁵ | 1.78 × 10⁻¹² | 159.1 |
| MoS₂ | | | | | |
| w/10 vol % | 532 | 0.30 | 16.7 × 10⁻¹⁵ | 3.21 × 10⁻¹² | 174.7 |
| MoS₂ | | | | | |
| w/20 vol % | 532 | 0.23 | 127 × 10⁻¹⁵ | 4.56 × 10⁻¹¹ | 134.2 |
| MoS₂ | | | | | |

[symbol]

indicates data missing or illegible when filed

Each item includes the photoresponsivity ( [symbol] ), noise current (noise current based on the root-mean-square), specific detectivity (D*), and linear dynamic range (LDR) values measured at the same wavelength (λ=532 nm). This allowed us to derive the optimal MoS₂ doping ratio.

As shown in Table 1, optimal performance was achieved in all [symbol] , D*, and LDR, when the MoS₂ addition concentration was 10 vol %.

Conversely, as the MoS₂ concentration gradually increases to 20 vol %, excessive inorganic addition disrupts the charge transport pathways due to the deterioration of organic crystallinity, and the increase in trap state causes a sharp rise in noise current and a reduction in linear dynamic range, leading to performance degradation.

These results demonstrate that the appropriate addition of MoS₂ contributes to improving the electrical and optical properties of the device. In particular, these results demonstrate the achievement of structural optimization that maintains a stable and wide linear dynamic range even under the high-light intensity conditions.

The embodiment of the present disclosure described above have been disclosed for illustrative purposes, and those skilled in the art with ordinary knowledge of the present disclosure will be able to make various modifications, changes, and additions within the spirit and scope of the present disclosure, and these modifications, changes, and additions should be regarded as falling within the scope of the following claims.

What is claimed is:

1. A method for manufacturing an organic photodiode, comprising:
forming a transparent electrode on a substrate;
forming an electron transport layer on the transparent electrode;
forming, on the electron transport layer, an organic bulk heterojunction photoactive layer having MoS₂ added at a predetermined volume percent relative to a total solution;
forming a charge transport layer on the organic photoactive layer; and
forming an upper electrode on the charge transport layer.

2. The method of claim 1, wherein the forming of the organic photoactive layer includes depositing a donor-acceptor mixed layer having MoS₂ added at a predetermined volume percent relative to the total solution onto a base matrix containing a 1:1 mixture of poly(3-hexylthiophene) (P3HT) as a donor and a fullerene derivative (ICBA) as an acceptor, by spin coating.

3. The method of claim 2, wherein the MoS₂ is mixed at 1 to 20 volume percent.

4. The method of claim 3, wherein the MoS₂ is mixed at 1 to 10 volume percent.

5. The method of claim 1, wherein the organic photodiode suppresses Langevin recombination, which occurs at increased light intensity due to the addition of the MoS₂, to maintain linearity in a high-light intensity region and keep a noise level in a low-light intensity region at a femtoampere (fA) range.

6. The method of claim 5, wherein the organic photodiode has a linear dynamic range (LDR) of at least about 170 dB and a detectivity of at least 3×10¹² Jones due to the addition of the MoS₂.

7. An organic photodiode, comprising:
a substrate;
a transparent electrode formed on the substrate;
an electron transport layer formed on the transparent electrode;
an organic photoactive layer formed on the electron transport layer and composed of an organic bulk heterojunction having MoS₂ added at a predetermined volume percent relative to a total solution;
a charge transport layer formed on the organic photoactive layer; and
an upper electrode formed on the charge transport layer.
